(19) United States
(12) Patent Application Publication
(10) Pub. No.: US 2019/0301004 A1
(43) Pub. Date: Oct. 3, 2019

(54) AMORPHOUS TUNGSTEN NITRIDE COMPOSITIONS, METHODS OF MANUFACTURE, AND DEVICES INCORPORATING THE SAME

(71) Applicant: KING ABDULLAH UNIVERSITY OF SCIENCE AND TECHNOLOGY, Thuwal (SA)

(72) Inventor: Abdulilah Mohammad MAYET, Thuwal (SA)

(21) Appl. No.: 16/134,113

(22) Filed: Sep. 18, 2018

Related U.S. Application Data
(60) Provisional application No. 62/651,861, filed on Apr. 3, 2018.

(51) Int. Cl. C23C 14/06; C23C 14/04; C23C 14/34; C23C 14/58; H01L 21/02; H01L 21/04

(52) U.S. Cl. CPC C23C 14/0641; C23C 14/042; C23C 14/3457; H01L 21/0425; C23C 14/5846; H01L 21/02266; H01L 21/02175; C23C 14/5873

(57) ABSTRACT

Amorphous tungsten nitride compounds, products, and methods of manufacture, as well as devices incorporating the same are disclosed herein. An example electro-mechanical device includes a first gate, a first drain, and a source having a completely amorphous metal tungsten nitride film cantilever. The cantilever extends from an anchor of the source transversely to the first gate and the first drain.

### CROSS-REFERENCE TO RELATED APPLICATION(S)

This non-provisional application claims the benefit and priority of U.S. Provisional Application Ser. No. 62/651,861, titled “AMORPHOUS METAL TUNGSTEN NITRIDE AND ITS APPLICATION FOR MICRO AND NANOELECTROMECHANICAL APPLICATIONS”, filed on Apr. 3, 2018, which is hereby incorporated by reference herein in its entirety, including all references and appendices cited therein, for all purposes.

### BACKGROUND

### Technical Field

Embodiments of the subject matter disclosed herein generally relate to perfectly amorphous (e.g., crystalline structure free) Tungsten Nitride alloy compositions, materials, and methods of manufacturing the same, as well as micro and/or nano-electromechanical devices incorporating the same.

### Discussion of the Background

Charge transport based solid state device oriented complementary metal oxide semiconductor (CMOS) electronics have reached a level where they are scaled down to nearly their fundamental limits regarding switching speed, off state power consumption and the on state power consumption due to the fundamental limitation of sub-threshold slope (SS) remains at 60 mV/dec. Nano-Electro-Mechanical (NEM) switches theoretically and practically offer the steepest sub-threshold slope and practically have shown zero static power consumption due to their physical isolation originated from the nature of their mechanical operation. Fundamental challenges remain with NEM switches in context of their performance and reliability including, but not limited to, necessity of lower pull-in voltage comparable to CMOS technology; operation in ambient/air; increased ON current and decreased ON resistance; scaling of devices and improved mechanical and electrical contacts; and high endurance.

Diminishing dimensions in CMOS devices have contributed to higher speed but at the cost of rising power consumption due to the unintended movement of charges even in the OFF state. As noted above, a fundamental limitation of sub-threshold slope (SS) remains at 60 mV/dec which limits faster switching from OFF to ON state and vice versa, which also results in higher dynamic power consumption.

Tunnel field effect transistor (TFET) and nanoelectromechanical (NEM) switches are two attractive options to lower the SS below present fundamental limitation of 60 mV/dec. Compared to TFET devices, NEM switches theoretically and practically offer the steepest SS and have shown nearly zero static power consumption due to their physical isolation originated from their mechanical operation. While choice of switch design can facilitate interesting attribute(s), and many NEM switches have been constructed, fundamental challenges remain with NEM switches in context of their performance and reliability. These parameters include necessity of lower pull-in voltage (Vₚᵢ) comparable to that of state-of-the-art CMOS technology, operation in ambient/air, increased ON current and decreased ON resistance, scaling of devices and improved mechanical and electrical contacts, and high endurance.

Therefore, there is a need to develop a metal or alloy that comprises material properties that overcome these drawbacks and satisfy the above parameters. Further, there is a need for MEM/NEM devices constructed with these materials that allow for improved performance and reliability.

### BRIEF SUMMARY OF THE INVENTION

According to an embodiment, there is an electro-mechanical switch having: a source; a gate; a drain; and an active element, the active element including a completely amorphous metal tungsten nitride film, the active element extending from an anchor of the source transversely to the gate and the drain.

According to another embodiment, there is a method for fabricating a totally crystalline cluster-free amorphous Tungsten nitride alloy film, the method including: sputtering a substrate using a Tungsten target using: (a) placing a substrate in a sputtering chamber; (b) placing a Tungsten target in the sputtering chamber on a sputtering tool; (c) selecting a separation distance between the Tungsten target and the substrate that is maximized in order to minimize adatom mobility of the totally crystalline cluster-free amorphous Tungsten nitride alloy film produced from the sputtering; (d) adjusting a chamber pressure within a range of approximately 30 mTorr to 5 mTorr, inclusive; (e) selecting a sputtering gas mixture ratio of Argon to Nitrogen; and (f) selecting a sputtering power profile for the sputtering tool of 300 W of alternating current.

According to yet another embodiment, there is a totally crystalline cluster-free amorphous Tungsten nitride alloy film including: a film fabricated from a mixture of Tungsten metal atoms and Nitrogen atoms, wherein the mixture is deposited in such a way that a totally crystalline cluster-free amorphous Tungsten nitride alloy film is created, where the totally crystalline cluster-free amorphous Tungsten nitride alloy film retains its totally crystalline cluster-free amorphous structure at any temperature.

### BRIEF DESCRIPTION OF THE DRAWINGS

For a more complete understanding of the present invention, reference is now made to the following descriptions taken in conjunction with the accompanying drawings, in which:

FIG. 1A is a flowchart of an example method for constructing a totally crystalline cluster-free amorphous Tungsten nitride alloy compound.

FIG. 1B is a flowchart of an example sputtering method that is used in conjunction with the method of FIG. 1A.

FIG. 10 is a flowchart of an example method for fabricating a NEM device.

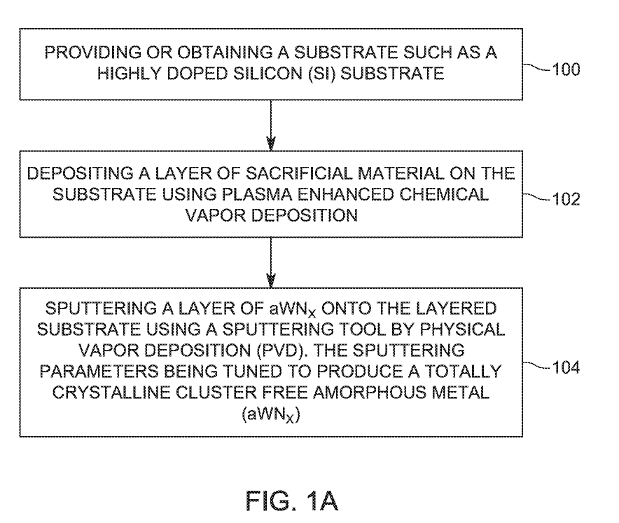

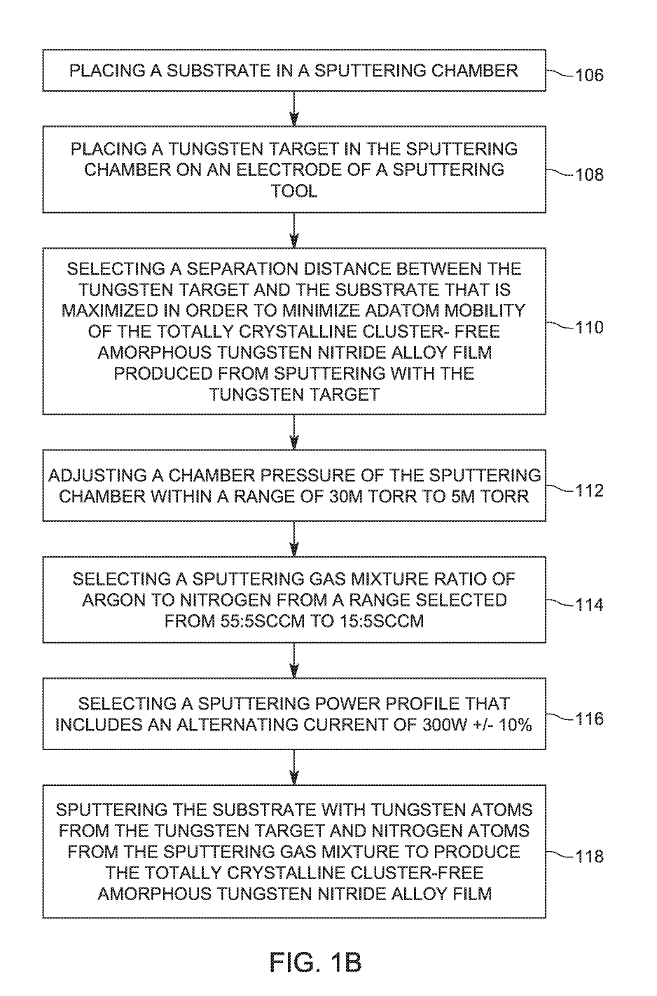

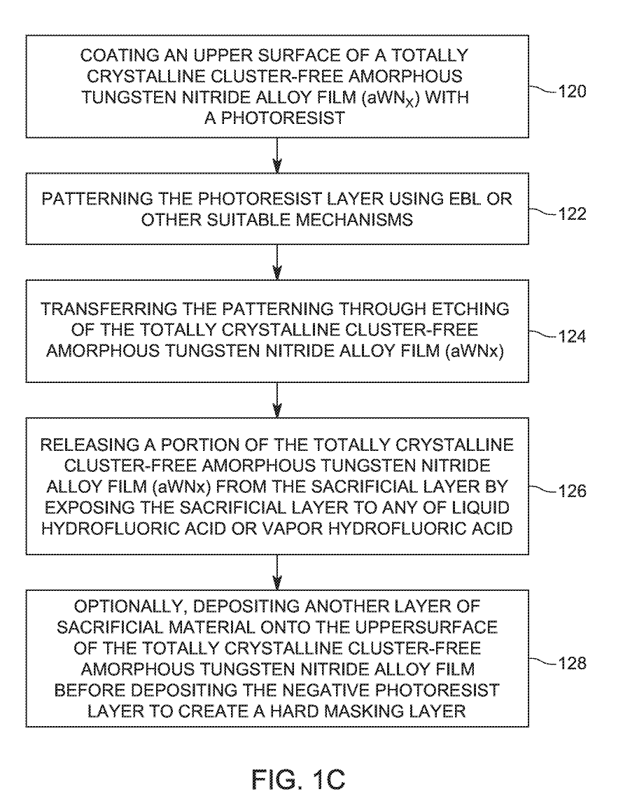

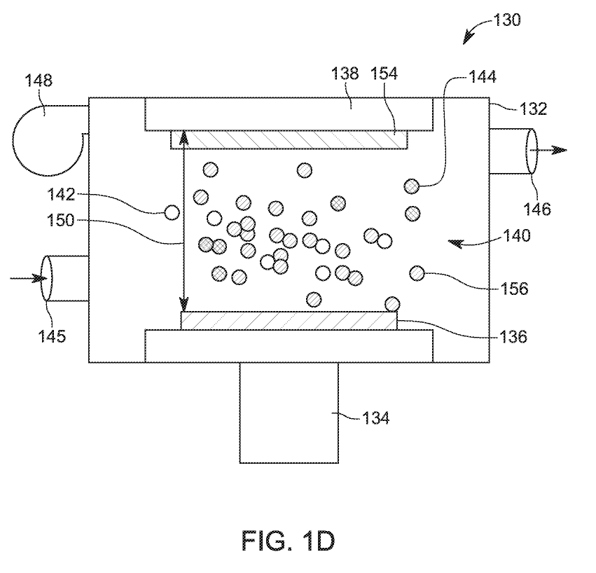

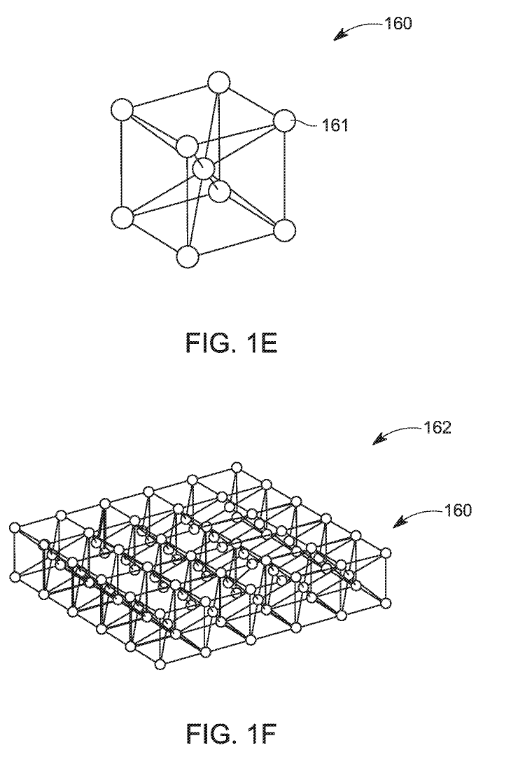

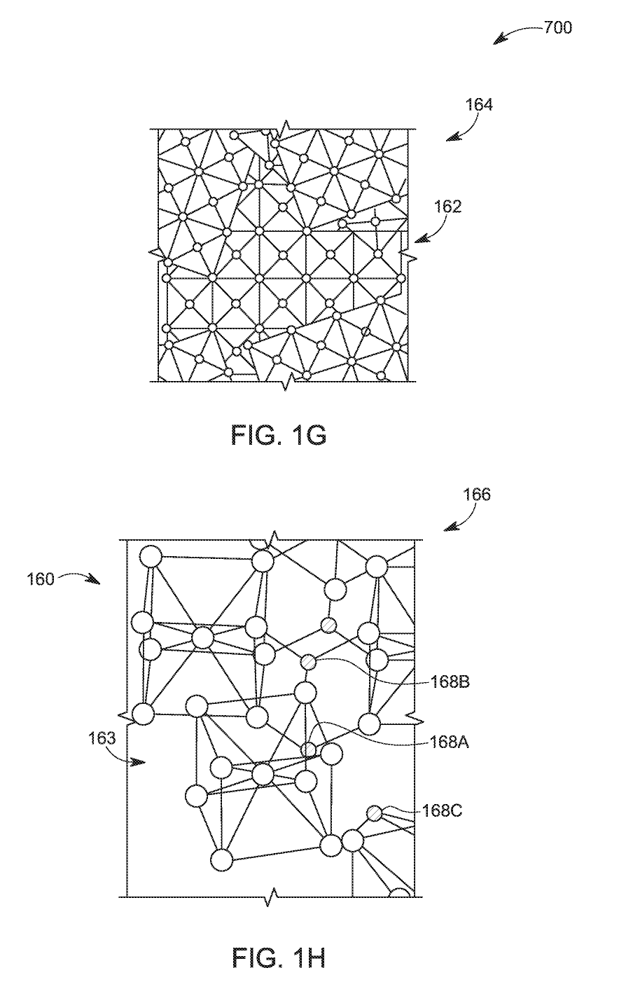

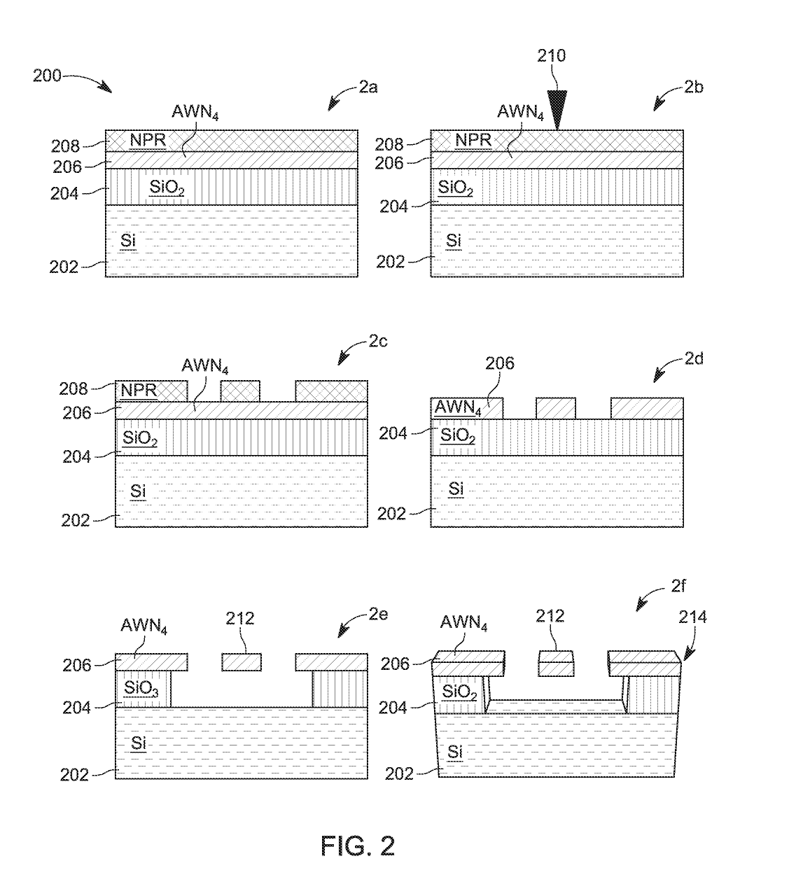

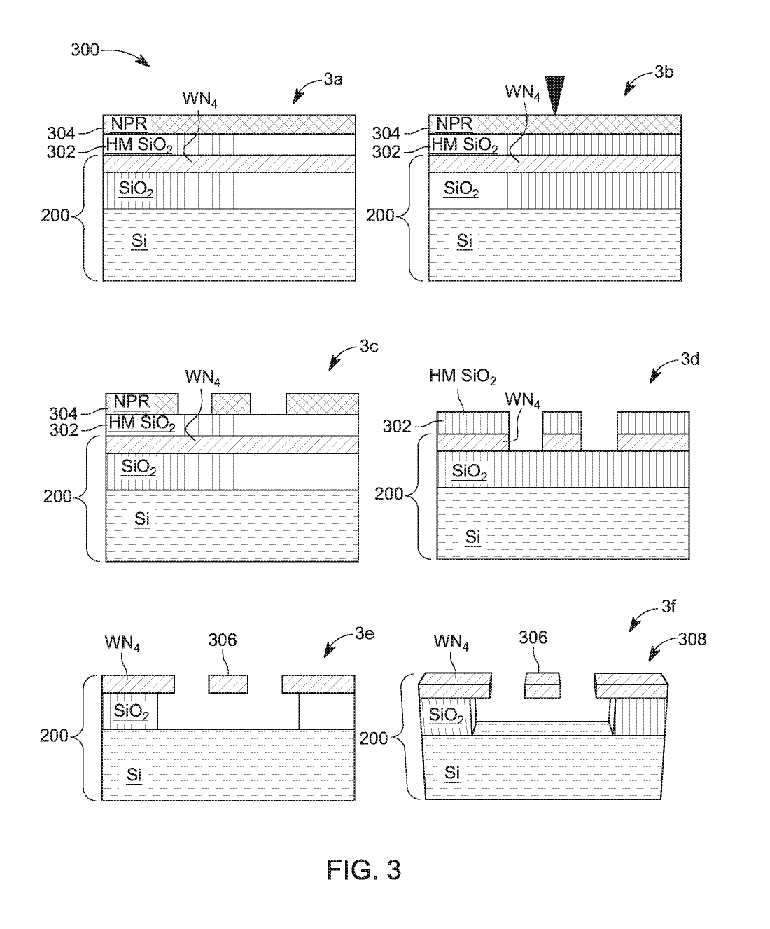

FIG. 1D is a schematic diagram of an example sputtering tool utilized to produce the aWNₓ materials of the present disclosure.

FIG. 1E is a perspective view of a molecular structure of an example single Tungsten crystal formed from Tungsten atoms.

FIG. 1F is a perspective view of an example crystalline Tungsten structure comprised of a plurality of single Tungsten crystals of FIG. 1E.

FIG. 1G is a top down view of an example polycrystalline Tungsten structure comprising an aggregation of a plurality of crystalline Tungsten structures of FIG. 1F interconnected together.

FIG. 1H is a perspective view of an example of a perfect (totally crystalline-structure free) aWNₓ molecular structure of the present disclosure.

FIG. 2, and views 2a-f thereof, collectively and diagrammatically illustrates an example process for manufacturing a NEM device comprising aWNₓ elements, the process using a photoresist layer.

FIG. 3, and views 3a-f, collectively and diagrammatically illustrate an example process for manufacturing a NEM device comprising aWNₓ elements, the process using a hard mask layer.

FIG. 4, and views 4a-f, collectively and diagrammatically illustrate an example process for manufacturing a NEM device comprising aWNₓ elements, the process using a nickel hard mask layer and/or positive photoresist layer.

FIGS. 5A and 5B collectively illustrate top-down plan views of an example single clamped lateral NEM device.

FIG. 6 is a top-down plan view of an example double clamped lateral NEM device comprising an aWNₓ element.

FIG. 7 is a perspective view of an example vertical NEM device comprising an aWNₓ element.

FIG. 8 is side view of an example bridge-style vertical NEM device comprising an aWNₓ element.

### DETAILED DESCRIPTION OF THE INVENTION

The following description of the exemplary embodiments refers to the accompanying drawings. The same reference numbers in different drawings identify the same or similar elements. The following detailed description does not limit the invention. Instead, the scope of the invention is defined by the appended claims.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

According to some embodiments, the present disclosure is directed to the creation and use of a totally crystalline cluster-free amorphous Tungsten nitride alloy, also referred to as a perfectly or completely amorphous Tungsten nitride alloy (aWNₓ for brevity). The present disclosure also contemplates electro-mechanical devices, such as switches, comprising perfectly amorphous Tungsten nitride alloy films. In one embodiment, a NEM (nano-electromechanical) switch is fabricated with an aWNₓ film. This switch is configured for sub-1 volt operation, and in some embodiments sub-0.3-volt operation, compatibility for use in air and vacuum environments, ON current as high as 0.5 mA and ON resistance lower than 5 kΩ, improved mechanical contact and continuous switching of eight trillion cycles for more than 10 days with an example switching speed of 30 nanoseconds without hysteresis.

As disclosed in greater detail herein, aWNₓ materials of the present disclosure are biodegradable. Thus the aWNₓ materials can be used in biodegradable electronics (also referred to as transient electronics) which physically disappear totally or partially after a given period of time or after performing a required function. To be sure, aWNₓ material dissolves in ground water at a rate of approximately 20-60 nm/h⁻¹. Thus, a 100 nm thick film of aWNₓ disappears in ground water in less than a day and three days are enough to dissolve completely a 300 nm thickness film.

As referenced above, micro and nano-electrochemical switches include metal or alloy components, either active or passive, that comprise crystalline structures. These crystalline structures are deleterious to performance. For context, NEM switches are mechanical switches that have an active element (mainly a movable cantilever which can be singly or doubly anchored) actuated (pulled) by electrostatic force (Fe) generated from a fixed and rigid electrode (e.g., gate). In terms of the present disclosure, embodiments herein have a cantilever and gate fabricated from aWNₓ materials, and in some embodiments only the cantilever is fabricated from aWNₓ material.

The cantilever and gate of the switch have an amorphous metal internal resistance Rₘ. A contact resistance R_{c} exists between the cantilever and the gate. A mechanical restoring force Fₘ is defined as the force required to return the cantilever back to a neutral position, whereas an electrostatic pulling force Fe is defined as a force required to pull an end of the cantilever into proximity of the gate and into electrical contact with the drain. There is also a capacitance between the gate and the cantilever defined as C_{g}. The active element (cantilever) and static part are analogous to capacitor facing plates. The active element has an inherent mechanical restoring force Fₘ, which opposes the external influence Fe exerted by the gate.

NEM switch operation embraces mechanical and electrical activities concurrently. The mechanical operations include, but are not limited to, acceleration, deceleration, hammering style impact, damping and oscillation. The electrical activities include, but are not limited to, electric charge, discharge, high current flow, charge accumulation and abrupt discharge. This complex operation of NEM switches cause the material of the active element (cantilever) as well as the electrode to deteriorate rapidly and shorten the lifetime of the switch, consequently impairing the electrical functionality. Most NEM switch defects are categorized into four main categories: electrical discharge damage to contact area, electrode weariness and deterioration, stiction, and mechanical failures (fracture or fatigue) of the active element—just to name a few. In general, the term stiction will be understood to comprise a friction force that prevents stationary surfaces from being set into motion relative to one another. NEM switches comprising aWNₓ materials as disclosed herein overcome these deficiencies.

In one embodiment, a vertically actuated three terminal NEM switch is in an operational mode when an active element such as a cantilever contacts an electrode such as a drain. Movement of the active element toward electrode by way of a gate causes a high accumulation of electric charges inversely proportional to the gap between them. This accumulation of charges could cause abrupt electric discharge (spark) especially with the existence of high surface roughness. This electric discharge could cause material melting (burn-out). Ablation and electrode surface damage occur as a direct result of electric discharge. At the contact point, the active element is exposed to three balanced forces; electrostatic force induced by the pull-in voltage, van der Waals force and Casimir force toward the electrode, and mechanical restoring force outward of electrode. Failing to restore the active element to its original position when the electrostatic force vanishes causes stiction.

Thus, the material of the active element can comprise a high spring constant (high Young's modulus) to prevent and/or reduce stiction. On the other hand, materials having a high Young's modulus require a high pull-in voltage, as these material properties are directly proportional to one another.

Most NEM switches have relatively smaller dimensions of gap and thickness in order to overcome stiction. In general, the thickness relates to the thickness of the cantilever and the gap refers to a space or distance between a contact surface of the cantilever and a contact surface of the electrode/drain.

Material fatigue or fracture is also a common issue with the cantilevers when fabricated from metals or alloys that are not perfectly amorphous. These failures normally occur near an anchor, which is the point where the cantilever contacts the source or base. This type of failure occurs because of grain boundary inter-stress and material defects.

These defects weaken the strength of the material and degrade the electrical and thermal conductivity. This failure is the origin of NEM switch unreliability and short lifetime, resulting in only a few million cycles at the most. Again, the NEM switches fabricated in accordance with the present disclosure overcome these failures.

The aWNₓ materials disclosed herein have a grain-less molecular structure unlike tungsten poly-crystalline structure of 50-100 nm grain size. Amorphous WNx is generally corrosion resistant, is highly endurable, has a smooth surface, has lower contact wear, and exacerbation resistance. It will be understood that the terms amorphous metal and metallic glass are not the same. Conventionally, the terminology metallic glass is used for non-crystalline metal formed by continuous cooling from a liquid phase. On the other hand, the terminology of amorphous metal is used for non-crystalline metal fabricated by methods other than from liquid, such as chemical vapor deposition (CVD) or physical vapor deposition (PVD).

Some embodiments disclosed herein include aWNₓ materials produced through reactive sputtering using a PVD tool with a Tungsten (W) target to form an aWNₓ film. Thus, tungsten and its nitride have a simple crystalline structure which can be easily altered to transform them into amorphous films. They are also commercially available, economical, and are CMOS compatible. Also, Tungsten, unlike most other type of metals, can be easily micro-machined with standard reactive ion etching (RIE) process using either sulfur hexafluoride (SF₆) or chlorine (Cl₂) gases.

Some embodiments involve a reactive ion etching process using chlorine (Cl₂) and oxygen (O₂) plasma to pattern an aWNₓ thin film. Furthermore, since this etching chemistry is selective to aWNₓ over silicon oxide (SiO₂), it is amenable to the use of a SiO₂ hard mask for high-aspect-ratio etching. It will be understood that the Tungsten nitride alloy of the present disclosure is a chemically stable compound due to its directional nature of the metal non-metal hybrid bonding.

A method for producing a totally crystalline cluster free amorphous metal is illustrated in general in FIG. 1A. The method includes a step 100 of providing or obtaining a substrate. For example, the substrate can be comprised of Silicon (Si) or another highly doped substrate.

Next, the method includes a step 102 of depositing a layer of sacrificial material on the substrate using plasma enhanced chemical vapor deposition or another similar process that would be known to one of ordinary skill in the art with the present disclosure before them. In one embodiment, the sacrificial layer is comprised of silicon dioxide (SiO₂) or another suitable silica compound. The silicon dioxide layer is deposited by a PECVD (plasma-enhanced chemical vapor deposition) tool. In some embodiments, the silicon substrate is cleaned to remove all the residuals polymers and impurities prior to receiving the sacrificial layer. A one to three μm thick film of SiO₂ is deposited by the PECVD tool. In some embodiments the silicon dioxide is deposited to have a thickness of approximately two μm. This process creates a layered substrate or material.

Next, the method includes a step 104 of sputtering a layer of aWNₓ onto the layered substrate using a sputtering tool by physical vapor deposition (PVD). The aWNₓ is sputtered onto the SiO₂ substrate, for example. An aWNₓ layer can be deposited with one of two different thicknesses based on intended use. In one embodiment, the aWNₓ layer is approximately 300 nm thick and is used for faster operation devices and the other is 500 nm thick for higher current flow devices. A more specific sputtering process is illustrated and described in greater detail infra with respect to FIG. 1B. The specific sputtering parameters disclosed herein produce a totally crystalline cluster free aWNₓ.

In FIG. 1B, a flowchart of an example sputtering process is illustrated. In general, the sputtering process is performed with a PVD sputtering tool. An example PVD sputtering tool is illustrated in FIG. 1D, which is described in greater detail infra. The method includes a step 106 of placing a substrate in a sputtering chamber. Next, the method includes a step 108 of placing a Tungsten target in the sputtering chamber on an electrode of a sputtering tool. The method also includes a step 110 of selecting a separation distance between the Tungsten target and the substrate that is maximized in order to minimize adatom mobility of the totally crystalline cluster-free amorphous Tungsten nitride alloy film produced from sputtering with the Tungsten target.

This separation is maximized in order to minimize adatom mobility of a totally crystalline cluster-free amorphous Tungsten nitride alloy film produced from the sputtering process. An example separation refers to a separation between a Tungsten target and a substrate, as will be discussed below with reference to FIG. 1D. In some embodiments, the separation distance is approximately 30 cm+/−20%, inclusive (in one example 24 cm to 36 cm, inclusive). It will be understood that maximizing the separation distance can be performed in an iterative process whereby surface roughness increases or decreases proportionally to the separation distance. Thus, the separation distance can be fine-tuned to minimize adatom mobility. Changes in adatom mobility are evidenced by changes in surface roughness of a resulting film. To be sure, less surface roughness is desired for the totally crystalline cluster-free amorphous Tungsten nitride alloy film produced for the reasons disclosed herein.

It will be understood that the terms adatom mobility refers to the tendency of adatoms (crystal surface layer atoms) to migrate across a surface of an object. Excessive adatom mobility can cause formation of surface artifacts leading to surface roughness.

The also includes a step 112 of selecting or adjusting a chamber pressure of the sputtering chamber within a range of 30 mTorr to 5 mTorr, as well as a step 114 of selecting or adjusting a sputtering gas mixture ratio of Argon to Nitrogen.

In one embodiment, the pressure is selected within a range of approximately 30 mTorr to 5 mTorr, inclusive, and a gas mixture ratio of approximately 55:5 sccm (Ar:N₂). In another embodiment, the pressure can be within a range of approximately 10 mTorr to 5 mTorr, inclusive.

The PVD sputtering tool chamber is filled with a sputtering gas mixture ratio of Argon and Nitrogen at ratio of approximately 35:5 sccm (standard cubic centimeter per minute). Other embodiments could include a range of ratios of Argon to Nitrogen from 55:5 sccm to 15:5 sccm.

In one or more embodiments, the method further includes a step 116 of selecting a sputtering power profile. In one embodiment the sputtering power profile includes an alternating current of approximately 300 W+/−10%. In some embodiments, the sputtering power profile is an alternating current of within a range of 250 W to 350 W, inclusive. In various embodiments the sputtering power profile includes an alternating current of 300 W.

The method also includes a step 118 of sputtering the substrate with Tungsten atoms from the Tungsten target and Nitrogen atoms from the sputtering gas mixture to produce the totally crystalline cluster-free amorphous Tungsten nitride alloy film.

To be sure, the resultant product of this process is a totally crystalline cluster-free amorphous Tungsten nitride alloy film that does not crystallize at temperatures of or above 480° C. This totally crystalline cluster-free amorphous metal is created using the specific sputtering conditions disclosed herein, or the inclusive ranges thereof. The methods of fabrication disclosed herein produce amorphous material properties that prevent the aWNₓ film from crystallizing at temperatures above 480° C., which is a common material property of metals and even metal glasses that will reorient to form crystals at high temperatures.

FIG. 1D is a schematic diagram of an example sputtering tool 130. The sputtering tool 130 can include a CVD or PVD sputtering tool. The sputtering tool 130 and contents generally comprises a sputtering chamber 132, a power source 134, a Tungsten target 136, and a substrate 138. In some embodiments, the sputtering chamber 132 is filled with a gas mixture 140 of Argon and Nitrogen at ratio of approximately 35:5 sccm. An example Nitrogen atom 142 and Argon atom 144 are illustrated. The gas mixture 140 is administered into the sputtering chamber 132 through port 145 and venting gas can exit through port 146. A pressure within the sputtering chamber 132 can also be selected of approximately 5 mTorr. This pressure within the sputtering chamber 132 can be regulated through the use of a pump 148.

In some embodiments, a separation distance 150 is defined by a space or distance between the Tungsten target 136 and the substrate 138. As noted throughout, this substrate 138 can include a silicon substrate or a multi-layer substrate having a silicon layer and a silicon dioxide layer. The separation distance 150 is maximized in order to minimize adatom mobility of a totally crystalline cluster-free amorphous Tungsten nitride alloy film 154.

The Tungsten target 136 is coupled with an electrode 135 that can be electrified using the power source 134. When electrified, Tungsten atoms, such as Tungsten atom 156, are ejected from the Tungsten target 136. As noted above, a sputtering power profile for the sputtering tool of 300 W of alternating current is selected in some embodiments. The Tungsten atoms and Nitrogen atoms combine within the sputtering chamber 132 and are deposited into a totally crystalline cluster-free amorphous Tungsten nitride alloy film 154 on top of the substrate 138. The mixture of Tungsten and Nitrogen atoms are drawn towards the substrate 138 using a negative electrical charge applied to the substrate 138.

FIGS. 1E-1H collectively illustrate structural differences between different Tungsten materials in view of molecular structure, including aWNₓ materials of the present disclosure. That is FIGS. 1E-1H collectively illustrate differences in molecular structure among crystalline, polycrystalline, and aWNₓ. To be sure, aWNₓ materials disclosed herein exhibit a high melting point, hardness, and electrical conductivity. The aWNₓ materials disclosed herein are a chemically stable compound due to their directional nature of the metal non-metal hybrid bonding.

FIG. 1E illustrates a molecular structure of a single Tungsten crystal 160 formed from Tungsten atoms 161. FIG. 1F illustrates a molecular structure of an example crystalline Tungsten structure 162 comprised of a plurality of single Tungsten crystals 160 as shown in FIG. 1E.

FIG. 1G illustrates a molecular structure of an example polycrystalline Tungsten structure 164 that includes an aggregation of a plurality of crystalline Tungsten structures interconnected together such as crystalline Tungsten structure 162.

In accordance with the present disclosure, a perfect (totally crystalline-free structure) aWNₓ molecular structure 166 is also illustrated in FIG. 1H, where no crystalline structures exist. Integration of nitrogen atoms 168A and 1688 prevent the formation of any crystalline Tungsten structure between adjacent Tungsten crystals, such as Tungsten crystal 160 and Tungsten crystal 163. Another nitrogen atom 168C is illustrated as preventing bonds between other adjacent Tungsten crystals. Stated otherwise, the perfect aWNₓ molecular structure 166 is comprised of a plurality of Tungsten crystals arranged in an amorphous manner due to the introduction of Nitrogen atoms during sputtering, which prevent Tungsten crystals from forming crystalline Tungsten structures 162 and/or polycrystalline Tungsten structures 164. In sum, the perfect aWNₓ molecular structure 166 is amorphous because it lacks both crystalline Tungsten structures and polycrystalline Tungsten structures.

Referring back to FIG. 1A, also in conjunction with FIG. 2, a multilayer substrate 200 is produced using steps 102-106 of FIG. 1A. The multilayer substrate 200 comprises the silicon substrate 202, the silicon dioxide sacrificial layer 204, and the aWNₓ layer 206. For purposes of clarity, the method steps used to further produce a manufactured component from the multilayer substrate 200 will be illustrated with reference to the diagrammatic illustrations of FIG. 2.

To begin preparing the multilayer substrate 200 for micromachining, the multilayer substrate 200 is coated by a negative photo resist (NPR) layer 208 as illustrated in cross-section view 2a. In some embodiments, because a hard mask is not used in this particular embodiment, a rigid and high etching resistant resist is used as it will withstand aggressive gases used for etching. Therefore, a resist SU8 (epoxy-based negative photoresist) is used after dilution to achieve thicknesses of approximately 300 nm to 500 nm after coating and baking. For embodiments where resulting devices have a nano-size structure, the resist thickness may not exceed three times the minimum feature size desired. Also, it will be understood that in some embodiments, a hard masking can be used, as will be discussed in greater detail infra.

SU8 resist is available commercially with high viscosities, which are suitable for coating thick layers from two μm up to 100 μm. SU8 is considered as an epoxy rather than NPR because SU8 has a high resistance to etching and high sensitivity for Ebeam exposure, typically more than 50 μC/cm². In some embodiments, Ebeam exposure of the multilayer material is performed using an electron beam lithography (EBL) device in order to pattern the multilayer material for etching.

The SU8 is diluted to have 300 nm to 500 nm thickness in some instances. For better adhesion and higher aspect ratio (AR) for SU8 resist, a post-exposure baking (PEB) at a temperature range of approximately 95° C. to 100° C. for one minute is used to dehumidify the multilayer substrate 200. Then the multilayer substrate 200 could be diced or cleaved manually for EBL exposure. In some embodiments, the multilayer substrate 200 is cleaved after the photoresist coating is applied so as to maintain uniformity of the photoresist coating.

Next, as illustrated in cross-section view 2b, the NPR layer 208 is patterned using EBL. To be sure, patterning a photoresist layer with nanostructure is a very sensitive and complex task. It will be understood that an Ebeam tool is represented generally by beam 210, has four variables that directly affect a minimum size of pattern exposure on the NPR layer 208. These variables comprise electron beam high voltage accelerator, exposure flashes density per die, electron beam current, and dwell time/exposure time.

Other than the electron beam high voltage accelerator (an inherent device property of the EBL), the other variables are selectable by the user. Existing Ebeam tools provide no proximity correction software which causes proximity error and over exposure of dense areas and under exposure of sparse areas. To overcome this issue, designs should take this issue into consideration in order to obtain optimal exposure parameters for EBL. The proximity error is generated by the scattered electron at exposure time.

Thus, a low current intensity is recommended for nano-size pattern exposure as expressed in the following equation:

$${d}_{p} = \sqrt{\frac{4 {i}_{p}}{β {π}^{2} {α}_{f}^{2}}}$$

where dₚ is an electron beam spot diameter; iₚ is a current intensity; β is a beam brightness, which is proportional to acceleration voltage; and α_{f} is a convergence angle of the Ebeam. For SUB, exposure conditions include beam dwell time of 0.30 μS. It will be understood that a fine-feature dwell time is doubled and the surrounding to be reduced to 10% to overcome any proximity error. Also, the exposure current is 50 pA, and exposure flashes density is 60,000 dots/1,200 μm die size.

Development (e.g., etching) of the NPR layer 208 is illustrated in cross-section view 2c. Next, as illustrated in cross-section view 2d, etching is performed to transfer the patterning of the NPR layer 208 produced by the EBL downwardly into the aWNₓ layer 206 and in some instances the sacrificial layer 204. To be sure, Tungsten is a transition metal and it is not easily etched, like most metals. Only a few gases are capable of etching tungsten, such as Cl₂, SF₆ and CF₄. The gas CF₄ causes polymer residuals at the side wall of the resulting device, therefore, it is not recommended to be used for lateral NEM switch fabrication. In some embodiments etching is performed with SF₆ according to the following parameters: an etching gas mixture of SF₆/Ar at a ratio of at or approximately 15/5 sccm; a pressure of at or approximately 20 mTorr; a power of at or approximately ICP 1000 W, platen 50 W; and a temperature of at or approximately 10° C. Again, these parameters are merely an example of selectable etching parameters, but can be varied according to device design requirements. Using the above parameters, an etching rate around 80 nm/min is achieved.

The selected gas ratio is very aggressive and etches the photoresist faster than the metal. Therefore, the metal thickness cannot be greater than the photoresist thickness. As noted above, the maximum thickness of the photoresist should not exceed three times the minimum feature size; otherwise the structure of the patterned photoresist will not be stable and may fall. Due to the limitation of the aWNₓ thickness that can be etched, the hard mask (HM) concept can be used and is described in greater detail infra (see FIG. 3).

After etching the aWNₓ layer 206, which is the main part of the NEM switches, the substrate is ready for NEM device release. There are two example methods to release the NEM device, either by liquid hydrofluoric acid (HF) or by vapor hydrofluoric acid (VHF) method. The use of liquid HF requires a special drying method to avoid stiction. For this reason, a critical point dryer (CPD) is used when liquid HF is utilized. The liquid HF releases the NEM device fully and makes the area beneath the released part very smooth, with very low residuals of SiO₂ or roughness. It will be understood that this method requires a long drying time by CPD, and the probability of stiction is increased.

Alternatively, the VHF method can be substituted because there is no submersion of the substrate into an acid required. The process includes exposing the substrate to a vapor HF at 40° C. This method leaves some residuals and roughness beneath the released part. The stiction probability is low, but the probability of not achieving full release is increased. An example method for releasing the NEM device by liquid HF includes submerging the layered substrate into the liquid HF for 15 seconds then submerging the layered substrate into deionized water for one to two minutes. Next, the layered substrate is submerged in three baths, a first of the baths in methanol and deionized water in a ratio of 20:80, a second of the baths in methanol and deionized water in a ratio of 50:50, and a third of the baths in methanol and deionized water in a ratio of 80:20. Finally the layered substrate is emerged in methanol in a CPD to dry it out thoroughly.

In the alternative VHF process, the NEM device is released by placing the layered substrate in a chamber for a period of time at 40° C. The period of time selected should be sufficient to allow for a lateral etching rate of at or approximately 50 nm/min. A released cantilever 212 is illustrated in cross-section view 2e, and a perspective, cross-sectional view of the NEM device 214 comprising the cantilever 212 is illustrated in view 2f.

In general, the NEM device 214 illustrated in view 2f is representative of an example switch 500 illustrated with respect to FIG. 5A. The view 2f is taken about line A-A of FIG. 5A.

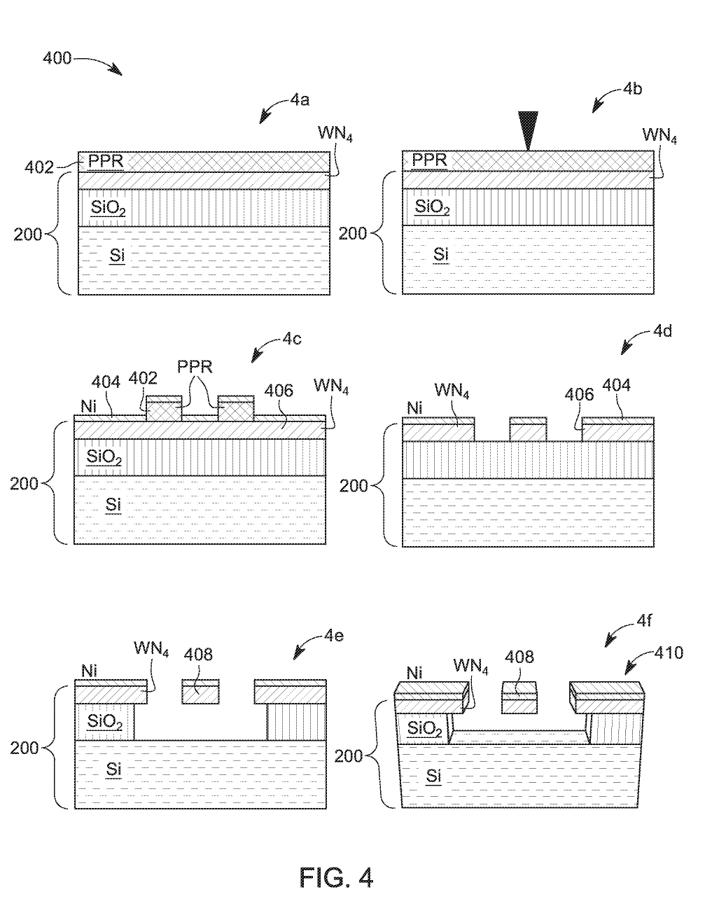

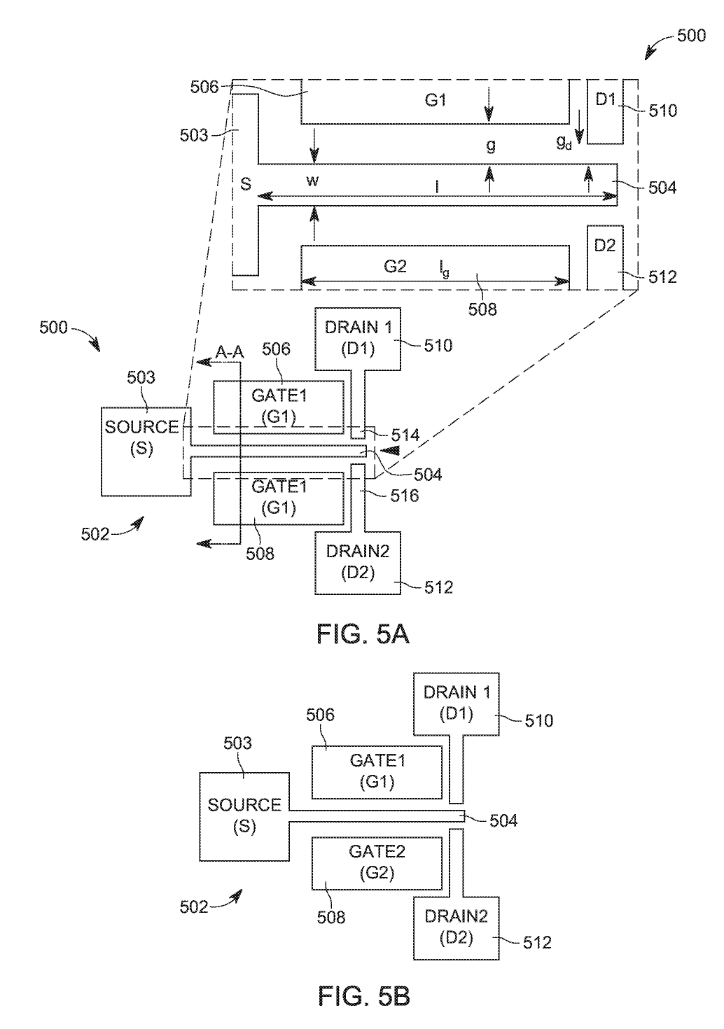

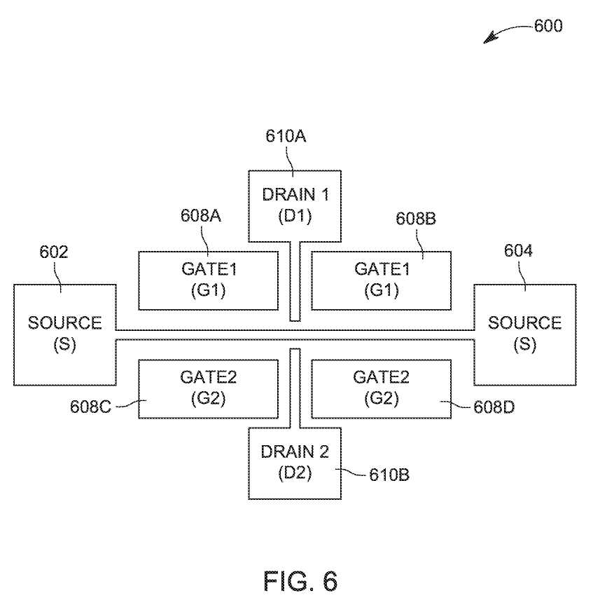

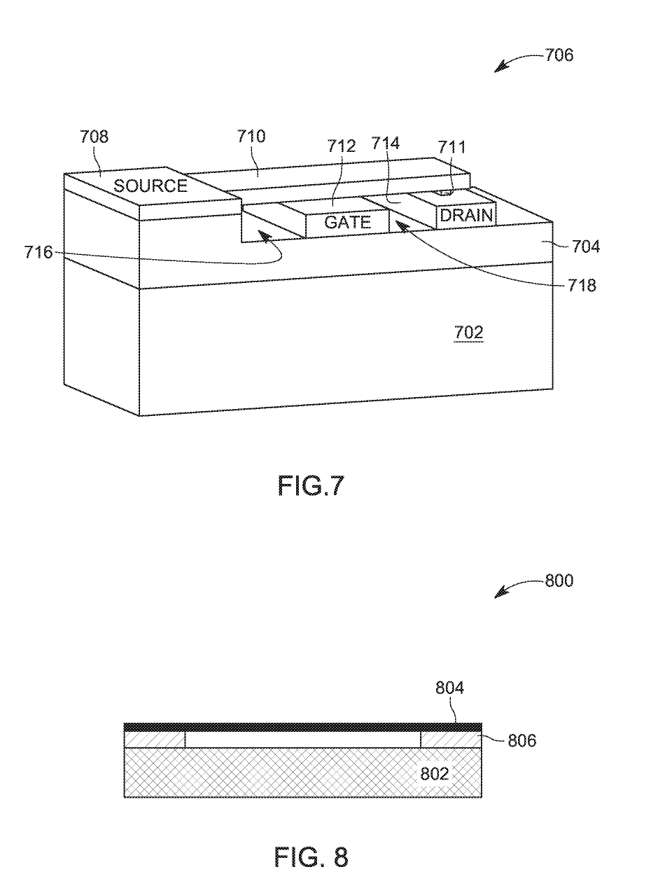

The process steps disclosed above in FIG. 2 are generally summarized in the flowchart of FIG. 10. In general, the method of FIG. 10 comprises a step 120 of coating an upper surface of the totally crystalline cluster-free amorphous Tungsten nitride alloy film with a photoresist layer. To be sure, this can include a totally crystalline cluster-free amorphous Tungsten nitride alloy film that is disposed as a layer on a substrate, in some embodiments.

Next, the method can include a step 122 of patterning the photoresist layer using EBL or other suitable mechanisms. The pattern that is transferred will provide the contours of a device such as a NEM switch. In some embodiments, the method includes a step 124 of transferring the patterning through etching of the totally crystalline cluster-free amorphous Tungsten nitride alloy film.

In one or more embodiments, the method includes a step 126 of releasing a portion of the totally crystalline cluster-free amorphous Tungsten nitride alloy film from the sacrificial layer by exposing the sacrificial layer to any of liquid hydrofluoric acid or vapor hydrofluoric acid. Releasing a portion of the aWNₓ creates the NEM device with static portions (source anchor, drains, gates, etc.) bound to the underlying layers of the multilayer substrate or material.

In various embodiments, the method can include an optional step 128 of depositing another layer of sacrificial material onto the upper surface of the totally crystalline cluster-free amorphous Tungsten nitride alloy film before depositing the negative photoresist layer to create a hard masking layer. As noted below, this is advantageous in embodiments where specific thicknesses of the aWNₓ layer are involved.

As noted above, another method of fabricating a NEM device includes the use of hard masking (HM). In general, photoresists are typically a polymer compound and its corresponding etch rate by any gas is much higher than the etch rate of a solid material beneath it, especially metals, and in the case of the devices of the present disclosure, when using aWNₓ.

It will be understood that FIGS. 1A-C can be considered collectively to describe an example process for fabricating a NEM device. This fabrication process combines aspect of aWNₓ creation and subsequent processing into a NEM device.

FIG. 3 illustrates a process using a hard mask. In one example embodiment, for etching a 300 nm thick aWNₓ layer, an example photoresist layer thickness is approximately 500 nm. However, this thickness is too great for sub-100 nm structures causing the structure to fall. Therefore, a hard mask (HM) layer is disposed on top of aWNₓ layer.

In cross-sectional view 3a, a multilayer substrate 300 is illustrated. This multilayer substrate 300 is identical to the multilayer substrate 200 of FIG. 2 with the exception that a hard mask layer 302 is disposed on top of the aWNₓ layer 206. A photoresist layer 304 is then deposited on the hard mask layer 302.

The photoresist layer 304 will be patterned and used to etch the hard mask layer 302. Then the hard mask layer 302 will be used to pattern and etch the aWNₓ layer 206. The process includes pattern transfer as illustrated in cross-section view 3b, and photoresist development/etching in cross-section view 3c. Cross-section view 3d illustrates transferring of a pattern from the photoresist layer 304 to the hard mask layer 302 through etching.

As noted above, SF₆ is a very aggressive gas that can etch most materials without selectivity. In this instance, Cl₂ mixed with O₂ can etch the aWNₓ with high selectivity of SiO₂ (in a ratio of 15:1). Another advantage of using SiO₂ as HM is that it will be etched away at the release step. A released cantilever 306 is illustrated in cross-section view 3e, and a perspective, cross-sectional view of the NEM device 308 is illustrated in view 3f.

Electron beam lithography (EBL) exposure parameters for the coated photoresist will be similar to the embodiment of FIG. 2. The adhesion of the photoresist layer 304 to the hard mask layer 302 (SiO₂) is stronger than the adhesion to a silicon or metal layer. Additionally, the exposed patterns have less proximity error due to smaller atoms of silicon and oxygen compared to Tungsten, which causes less EBL scattering. Therefore, the EBL current flow is increased for exposure. Proximity correction should be re-evaluated because of the material exposed beneath the photoresist layer 304. After exposure, the photoresist layer 304 should be developed as mentioned above.

The hard mask layer 302 is etched using the following example etching parameters: C₄F₈/O₂ at approximately a ratio of 40/5 sccm; a pressure of approximately 10 mTorr; a power of approximately ICP 1500 W, platen 100 W; and a temperature of approximately 10° C., each of these parameters being inclusive. In some embodiments, the photoresist layer 304 is ashed after etching the hard mask layer 302 to avoid polymer deposition when the aWNₓ layer is etched. In general, ashing the photoresist layer 304 comprises any suitable process whereby the photoresist layer 304 is burned into an ash. An example etching rate is 240 nm/min using the disclosed etching parameters.

The aWNₓ is developed/etched using the following example parameters: exposure to a ratio of approximately Cl₂/O₂ at 30/5 sccm; pressure of approximately 5 mTorr; power of approximately ICP 1000 W, platen 200 W; and temperature of approximately 80° C., each of these parameters being inclusive. The etching rate is approximately 300 nm/min using the disclosed etching/developing parameters.

Another example fabrication method includes a bottom-up lift off method. In this method aWNₓ is deposited on top of the patterned layer of photoresist. Then, the photoresist is removed and the unwanted material (such as a sacrificial material) on top of the photoresist is lifted off with the photoresist (referred to as a lift-off process). It will be understood that there is no need for etching in this process. If the method includes an EBL process, a positive photoresist (PPR) is utilized to minimize exposure time.

FIG. 4 illustrates a multilayer substrate 400 that is identical to the multilayer substrate 200 of FIG. 2 with the exception that a hard mask layer 404 of nickel is present and disposed below a photoresist layer photoresist layer 402.

According to some embodiments, a hybrid process is utilized that comprises a combination of both bottom-up and the top-down processes. In these methods, a hard mask layer is deposited with the lift-off process (bottom-up) disclosed above and the aWNₓ is etched as in the top-down process. In this process, nickel (Ni) is selected for the hard mask layer 404 because nickel has a very high etching resistivity for both aggressive gases, SF₆ and Cl₂. The process steps have been illustrated in the views 4a-f of FIG. 4.

In more detail, the cross-sectional view 4a illustrates a positive photoresist layer 402 disposed on a multilayer substrate that includes an upper layer of aWNₓ 406. The positive photoresist layer 402 is patterned in cross-sectional view 4b and the development of the positive photoresist layer 402 and deposition of nickel is illustrated in cross-sectional view 4c. The deposition of Ni is performed using an e-Beam evaporator in one embodiment although other methods are likewise contemplated for use. This step is unique to this hybrid process. The Ni layer is deposited by Ebeam evaporator. Small pieces of Ni (chips) are placed inside an alumina crucible evaporated by electron beam. The thickness of the hard mask layer 404 is approximately 30 nm using a deposition rate of about 2 nm/min. Again, these thickness parameters will vary according to design requirements. Then the substrate is submerged in acetone with agitation to remove the PR and lift off the excess nickel off its upper surface.

Cross-section view 4d illustrates removal of the positive photoresist layer 402 and transfer of the pattern from the hard mask layer 404 to the aWNₓ 406. A released cantilever 408 through VHF is illustrated in cross-section view 4e, and a perspective, cross-sectional view of the NEM device 410 is illustrated in view 4f.

Irrespective of the method used to create an aWNₓ film, material and mechanical properties of an example aWNₓ film are disclosed. A mechanical strength of a 1 μm thickness layer of aWNₓ film was evaluated using a nano-indentation tool (static load ranging from 30001 to 400001, with a deflection ranging from 20 nm to 170 nm). The Young's modulus of the sample was found to be 300 GPa, while the hardness was found to be 3 GPa. These high values of elasticity and hardness together with the grain-less amorphous structure have significant advantage in strengthening NEM switches against stress and deformation. This is indicative of a longer operational lifetime and less contact resistance. The existence of nitrogen atoms among the tungsten atoms reduces the tendency of native oxide formation as noted from the four probe sheet resistance measurement. The sheet resistance was 200μΩ·cm and remained constant being measured just after deposition and again after four weeks exposure in normal ambient air with an average daily humidity of 70% or above. The deposited aWNₓ possessed a density, 17.5 g/cm³. This value lies between the hexagonal crystalline (δ-WN, 18.1 g/cm³) and cubic crystalline (δ-W²N, 16.1 g/cm³) densities. The deposited film has a slightly tensile stress, 500 MPa, which is advantageous to avoid sagging of the cantilever of the switch, thanks to the strain gradient.

A surface roughness of the deposited layer of aWNₓ was characterized using atomic force microscope (AFM) Agilent 5500 SPM using the intermittent contact imaging mode. It was found that the average value of surface roughness is 2.53 nm for a projected area of 64 μm². The median value is 2.31 nm with the maximum value of 30 nm and minimum value of nearly 0 nm. Both the amorphous nature and the smooth surface of the material yield a reduction of electric discharge phenomenon which prevents micro-welding failures by reducing the amount of energy stored in the active element of the NEM switch. The aWNₓ material of the present disclosure, with its smooth contact surface, does not pile up charges at sharp spikes, and further its stronger molecular bonds via closed pack atomic density prevent oxidation. Consequently, this helps in achieving a moderate contact resistance to prevent excess charge passage. Additionally, due to the high hardness of aWNₓ, the electrode and active element (source/cantilever) in the NEM switches are highly resistant to ablation and wearing.

As noted above, a lack of enough mechanical restoring force may cause stiction in MEM or NEM devices. An aWNₓ film of the present disclosure with fairly high Young's modulus (300 GPa) reflects a high value of spring constant. This gives an adequate mechanical force to pull back the active element after removing the electrical pull-in force, thus eliminating the need for a high pull back voltage. Other causes of stiction between the active element and the electrode are Van der Waals force as well as Casimir force. One way to overcome them is to have high enough mechanical force, but not too high that it increases a pull-in voltage, as Vₚᵢ is directly proportional to the restoring force. In contrast with aWNₓ, silicon made NEM switches have higher probability for stiction due to their low Young's modulus (about 160 GPa). On the other hand, a material with high value of Young's modulus has almost no stiction issue, such as amorphous carbon, carbon nanotube (CNT) and silicon carbide (SiC), where the value is around 700 GPa. The aWNₓ disclosed herein has an intermediate Young's modulus value which overcomes the stiction issue that exists in silicon based NEM switches and does not require high operating voltage, which is required by carbon based material.

Finally, mechanical failure occurs in MEM and NEM switches because of the cluster boundary existence, which can cause fracture, deformation, material fatigue, or combinations thereof. The boundaries among the grains are the weakest point in the material (weakest link in the chain) and fractures occur at these boundaries. These defects shorten the lifespan of the device tremendously. Therefore, the material used to fabricate the NEM switches needs to be either mono-crystalline or amorphous to overcome this defect of poly-crystalline material. Since mono-crystalline metal is not possible through conventional CMOS processes, therefore, amorphous metal such as the aWNₓ disclosed herein will perform in a superior manner.

The following paragraphs describe example embodiments of NEM switches that can be fabricated to include aWNₓ materials disclosed herein. An aWNₓ film is used as active elements such as cantilevers and electrodes. It will be understood that the electrodes of an NEM switch include both drains and gates. Thus, in some embodiments all elements of the switch are fabricated from an aWNₓ that has been machined into a switch design. FIG. 5A illustrates (including a close up view) an example lateral single clamped NEM switch (referred to as switch 500). A view relative to section line A-A is illustrated in FIG. 2, and specifically views 2e and 2f.

The switch 500 comprises a source 502 having an anchor portion 503 and a cantilever 504 extending therefrom (also referred to as an active element). The source 502 is fabricated from the aWNₓ material of the present disclosure. The switch 500 is illustrated in the idle position in FIG. 5A. The cantilever 504 extends transversely to a pair of gates and a pair of drains. The pair of gates and pair of drains can also be fabricated from the aWNₓ material of the present disclosure. More specifically, the cantilever 504 extends between a first gate 506 and a second gate 508 and is equidistantly spaced from each (g). The cantilever 504 also extends between a first drain 510 and a second drain 512, and more specifically, between terminal ends 514 and 516 of the first and second drains, respectively. The terminal ends of the first and second drains extend as elongated members from the bodies of the first and second drains. The space or gap (g_{d}) exists between the terminal ends of the first and second drains and the cantilever 504. The cantilever has a width (w) and length (I). Gates, such as second gate 508 have a length (I_{g}).

A potential difference is applied between the cantilever 504 and any of the gates to generate an attractive electrostatic force which pulls the cantilever towards one of the gates in order to allow a terminal end of the cantilever 504 to contact one of the drains. As the cantilever 504 moves towards one of the gates, when it reaches one-third of the initial gap (g) distance between the cantilever 504 and one of the gates, the cantilever 504 will fall towards the active (e.g., electrified) gate. This distance is called the pull-in distance and the voltage required to move the cantilever 504 to the pull-in distance is called the pull-in voltage.

FIG. 5B illustrates the switch 500 in an actuated or active position. This position is created when either the second gate 508 produces an electrostatic pulling force that overcomes the mechanical restoring force of the cantilever 504. The end of the cantilever 504 contacts the second drain 512 to complete the switch circuit. Alternatively, the first gate 506 can be used to bring the end of the cantilever 504 into contact with the first drain 510.

To ensure that the cantilever 504 makes contact with a drain, each drain should not be separated from the cantilever 504 more than the pull-in distance, otherwise the system might collapse when instead the cantilever 504 makes contact with any of the gates. In the case of a singly clamped cantilever, a drain can be located at a free end of the cantilever 504.

FIG. 6 illustrates an example lateral dual clamped NEM switch (referred to as switch 600). Again, all or a portion (such as only the source) of the switch can be fabricated from the aWNₓ material of the present disclosure. The switch comprises a source that is divided in a first source portion 602 and a second source portion 604 with a cantilever 606 extending therebetween. The cantilever 606 is clamped at one end at the first source portion 602 and at an opposing end at the second source portion 604. In general, the source comprised of the first source portion 602, the second source portion 604, and the cantilever 606 are fabricated from the aWNₓ material of the present disclosure.

In various embodiments, the switch 600 comprises four gates 608A-D and two drains 610A-B. Each of the four gates 608A-D and the two drains 610A-B can also be fabricated from the aWNₓ material of the present disclosure. The cantilever 606 extends transversely to the four gates 608A-D and two drains 610A-B. The cantilever 606 is equidistantly spaced from each of the four gates 608A-D. The cantilever 606 is equidistantly spaced from each of the two drains 610A-B, but the space between the cantilever 606 and contact surfaces of the two drains 610A-B is less than the space between the cantilever 606 and contact surfaces of the four gates 608A-D. Again, this distance is based on a pull-in distance requirement and the difference in distances ensures that the cantilever 606 will contact a terminal end of a drain without collapsing into or contacting a gate.

Of note, the two drains 610A-B are each located at a middle point of the cantilever 606. For example, one drain 610A extends between gates 608A and 608B, while another gate 610B extends between gates 608C and 608D.

In operation, a potential difference between a gate and a cantilever (source) is called gate voltage. The applied induces opposite polarity charge on the facing side of the cantilever. Consequently, this opposing polarity of charges generates electrostatic force (Fe) which pulls the cantilever toward a gate, according to the following formula:

$${F}_{e} = \frac{1}{2} \frac{{CV}^{2}}{{d}_{o}}$$

where dₒ is a distance between cantilever and gate, sometimes called the gap (g); V is a potential difference between cantilever and gate, and C is capacitance.

As the cantilever starts moving, there will be a mechanical counter-force or restoring force (Fₘ) of the cantilever material is directly proportional to the spring constant of the cantilever material. The restoring force is calculated by the following equation:

Fₘ=k*d

Spring constant (k) should be calculated using a formula of distributed pressure instead of the point load pressure for lateral NEM switches which is calculated using the following equation:

$$k = \frac{2 {Etw}^{3}}{3 {l}^{3}}$$

where E is Young's modulus; d is cantilever tip distance travel; I is cantilever length; w is cantilever width; t is cantilever thickness; and k is a spring constant.

The gate voltage is calculated by the following formula:

$${V}_{pi} = \sqrt{\frac{8 {kd}_{o}^{2}}{27 {C}_{g}}}$$

where dₒ is the gap between cantilever and gate; sometimes called (g); C_{g} is the capacitance between the cantilever and the gate; and k: the spring constant.

The pull-in distance (dₚᵢ) is measured from the moving side, which is the cantilever side. The pull-in distance (dₚᵢ) is calculated using the following formula:

$${d}_{pi} = \frac{{d}_{o}}{3}$$

This phenomenon adds some challenges in NEMS fabrication because it is utilized to ensure a gap between the cantilever and the drain does not exceed one-third of the initial distance between the cantilever and the gate gap. From the expression above it is clear that varying the dimensions will directly affect the Vₚᵢ.

For sub-1 volt NEM switches, the dimensions must be in the range of nanometers. A nanoscale dimension is reachable by a deep ultraviolet (DEV) or electron beam lithography (EBL) tool. As noted above EBL has been used to fabricate the NEM switches.

FIG. 7 illustrates an example vertical NEM switch (referred to as switch 700), constructed in accordance with the present disclosure. The switch 700 comprises a silicon structural layer 702, a sacrificial silicon dioxide layer 704 and an aWNₓ layer 706 that is machined and/or otherwise processed to create a source 708 with a cantilever 710, along with a gate 712, and a drain 714. In some embodiments, the cantilever 710 comprises a protrusion 711 on an underside that faces an upper surface of the drain 714. This protrusion 711 lessens the space between the end of the cantilever 710 and the drain 714, thereby altering the pull-in force and voltage.

In general, a vertical NEM switches requires more steps of fabrication process than lateral NEM switches disclosed above. A single mask is not enough to fabricate a three terminal vertical NEM switch (source, gate, and drain), the process demands multiple masks. In some embodiments, a minimum of three masks are required. One mask is used to pattern and etch the gate 712 and drain 714, another mask is used to pattern and etch for dimple(s) 716 and 718, and the last mask is used to pattern and etch for the cantilever 710.

Planarization steps are needed after depositing a sacrificial layer above the gate and drain. Without planarization for the sacrificial layer, the cantilever will follow the profile of the underlying layers. A non-straight cantilever profile limits the operation and the lifetime of the switch 700. Generally, in some embodiments, the silicon structural layer 702 functions as a substrate, the gate 712 and drain 714 are deposited on top of an electrically isolating layer which is the sacrificial silicon dioxide layer 704.

To avoid the cantilever having a topographical contour, a two terminal vertical NEM switch 800 can be produced as illustrated in FIG. 8. The substrate 802 will act as the gate, and a top structure 804 will act as the cantilever. Between the substrate 802 and top structure 804 is a layer of sacrificial/support material 806.

Unlike with lateral switches, the fabrication of vertical switches does not need EBL because the critical dimensions are the thickness of the cantilever and the gap between the cantilever and the gate. A layer deposition tool controls these two variables, not the lithography step. Contact aligner with broad ultraviolet (BUV) lamp can be alternatively used for the lithography process to fabricate vertical NEM switches. The dimensions of the gate, drain, dimple and cantilever are in the range of microns, but the thickness of the cantilever and the sacrificial layer are in the range of nanometers.

To be sure, the embodiments of FIGS. 5-8 are illustrative and descriptive but not limiting unless claimed as such. Moreover, the manufacturing processes and aWNₓ materials disclosed herein can be utilized any manner desired as would be appreciated by one of ordinary skill in the art with the present disclosure before them.

As noted above, the aWNₓ fills a demand for biodegradable material for sustainable devices. Also, aWNₓ fills of the present disclosure will degrade when exposed to ground water as disclosed supra. These dissolution characteristics of the present aWNₓ are used to fabricate safety switches for sensitive devices. For example, a high density of aWNₓ gives a preference to fabricate high sensitivity inertia based sensors such as accelerometers and gyroscopes. WNₓ dissolution characteristics are used for final tuning the mass of the switch according to special circumstances. In addition, different dissolution rates for different solutions are utilized to fabricate ion and salt sensors.

In some embodiments, the present disclosure includes methods for constructing biodegradable or transient electronics. The methods include determining a desired biodegradation time or a function time for the electronics. For example, it may be desired that the electronics should only function for a certain number of cycles before the electronics biodegrade. In another example, a biodegrade time is selected in lieu of function. For example, a certain application involves allowing an electronic device comprising aWNₓ materials to operate until they have degraded through water contact. In yet other embodiments, an electronic device can be constructed to include aWNₓ materials and for these aWNₓ materials to be intentionally exposed to water or other fluids in order to degrade the aWNₓ materials.

Thus, a method could include a step of deploying a totally crystalline cluster-free amorphous Tungsten nitride alloy (aWNₓ) film in an electro-mechanical device for an operational duration of time. The totally crystalline cluster-free amorphous Tungsten nitride alloy film biodegrades during the operational duration of time of the electro-mechanical device.

The biodegradable aspects of aWNₓ materials allow them to be used for electronics such as secure memory storage in one example use case. When it becomes necessary to destroy data residing on the secure memory storage made from aWNₓ materials, the secure memory storage is exposed to water or other fluid resulting in irreparable damage to the secure memory storage.

The aWNₓ materials disclosed herein are very attractive for fabricating sensors because of a high resonance frequency and quality factor. In addition, aWNₓ is harsh environment resistant and expendable. Different bio-sensors could be fabricated using this material. In addition, aWNₓ can be used for high security military devices fabrication for the mentioned characteristics based on the ability of the aWNₓ to quickly degrade.

Also, the aWNₓ materials disclosed herein are highly conductive (metal like) and could be used for high power and high current flow devices. The aWNₓ materials have a relatively high hardness, elasticity, and moderate surface roughness and contact resistance give the aspect of non-welding and no hysteresis operation. Therefore, there will be minimum energy loss and welding effect of high current flow.

It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present exemplary embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

What is claimed is:

1. A method for fabricating a totally crystalline cluster-free amorphous Tungsten nitride alloy film, the method comprising:
placing a substrate in a sputtering chamber;
placing a Tungsten target in the sputtering chamber on an electrode of a sputtering tool;
selecting a separation distance between the Tungsten target and the substrate that is maximized in order to minimize adatom mobility of the totally crystalline cluster-free amorphous Tungsten nitride alloy film produced from sputtering with the Tungsten target;
adjusting a chamber pressure of the sputtering chamber within a range of 30 mTorr to 5 mTorr;
selecting a sputtering gas mixture ratio of Argon to Nitrogen from a range selected from 55:5 sccm to 15:5 sccm;
selecting a sputtering power profile for the electrode of the sputtering tool to be within a range of 250 W to 350 W of alternating current; and
sputtering the substrate with Tungsten atoms from the Tungsten target and Nitrogen atoms from the sputtering gas mixture to produce the totally crystalline cluster-free amorphous Tungsten nitride alloy film.

2. The method according to claim 1, wherein the separation distance is selected from a range of 24 cm to 36 cm, inclusive.

3. The method according to claim 1, further comprising:
applying a silicon dioxide mask to at least a portion of an upper surface of the totally crystalline cluster-free amorphous Tungsten nitride alloy film.

4. The method according to claim 1, wherein the totally crystalline cluster-free amorphous Tungsten nitride alloy film does not crystallize at temperatures at or above 480° C.

5. The method according to claim 1, further comprising:
coating an upper surface of the totally crystalline cluster-free amorphous Tungsten nitride alloy film with a negative photoresist layer;
patterning the negative photoresist layer;
transferring the patterning through etching of the totally crystalline cluster-free amorphous Tungsten nitride alloy film; and
releasing a portion of the totally crystalline cluster-free amorphous Tungsten nitride alloy film from a sacrificial layer by exposing the sacrificial layer to any of liquid hydrofluoric acid or vapor hydrofluoric acid.

6. The method according to claim 5, further comprising:
depositing another layer of sacrificial material onto the upper surface of the totally crystalline cluster-free amorphous Tungsten nitride alloy film before depositing the negative photoresist layer to create a hard masking layer.

7. The method according to claim 1, further comprising:
coating a lower surface of the totally crystalline cluster-free amorphous Tungsten nitride alloy film with a positive photoresist layer;
transferring a pattern to the positive photoresist layer;
transferring the pattern of the positive photoresist layer through etching of the totally crystalline cluster-free amorphous Tungsten nitride alloy film; and
lifting the etched totally crystalline cluster-free amorphous Tungsten nitride alloy film away from the positive photoresist layer.

8. The method according to claim 1, further comprising:
deploying the totally crystalline cluster-free amorphous Tungsten nitride alloy film in an electro-mechanical device for an operational duration of time,
wherein the totally crystalline cluster-free amorphous Tungsten nitride alloy film biodegrades during the operational duration of time.

9. A material comprising:
a film fabricated from a mixture of Tungsten metal atoms and Nitrogen atoms,
wherein the mixture is deposited in such a way that a totally crystalline cluster-free amorphous Tungsten nitride alloy film is created,
wherein the totally crystalline cluster-free amorphous Tungsten nitride alloy film retains its totally crystalline cluster-free amorphous structure at any temperature.

10. The totally crystalline cluster-free amorphous Tungsten nitride alloy film according to claim 9, wherein the totally crystalline cluster-free amorphous Tungsten nitride alloy film comprises a sheet resistance of approximately 200μΩ·cm, and a density of approximately 17.5 g/cm³.

11. The totally crystalline cluster-free amorphous Tungsten nitride alloy film according to claim 10, wherein the totally crystalline cluster-free amorphous Tungsten nitride alloy film comprises a surface roughness having an average value of 2.53 nm for a projected area of 64 μm² and a median value of approximately 2.31 nm to reduce micro-welding failures between the totally crystalline cluster-free amorphous Tungsten nitride alloy film and a gate of a switch into which the totally crystalline cluster-free amorphous Tungsten nitride alloy film is incorporated as a source and cantilever.

12. The totally crystalline cluster-free amorphous Tungsten nitride alloy film according to claim 9, wherein the totally crystalline cluster-free amorphous Tungsten nitride alloy film has a Young's modulus of 300 GPa and a thickness of 100 nm.

13. An electro-mechanical switch, comprising:
a first gate;
a first drain; and
a source comprising a completely amorphous metal tungsten nitride film cantilever, the cantilever extending from an anchor of the source transversely to the first gate and the first drain.

14. The electro-mechanical switch according to claim 13, further comprising:
a second gate and a second drain, the cantilever being disposed between the first gate and the second gate, as well as the first drain and the second drain.

15. The electro-mechanical switch according to claim 14, further comprising:
a third gate and a fourth gate, the drain extending between the first gate and the third gate, the second drain extending between the second gate and the fourth gate.

16. The electro-mechanical switch according to claim 15, wherein the source comprises a first source portion and a second source portion, the cantilever being coupled to both the first source portion and the second source portion.

17. The electro-mechanical switch according to claim 13, further comprising:
a protrusion disposed on a contact surface of the cantilever above the first drain.

18. The electro-mechanical switch according to claim 13, wherein the cantilever is configured to contact the drain when electrified by the source at a voltage that is less than one volt, further wherein the cantilever comprises an ON current up to 0.5 mA and an ON resistance lower than 5 kΩ.

19. The electro-mechanical switch according to claim 18, wherein the cantilever has a Young's modulus of 300 GPa and a thickness of 100 nm.

20. The electro-mechanical switch according to claim 13, wherein the electro-mechanical switch is capable of continuous switching of 8 trillion cycles for more than 10 days, and comprises a switching speed of 30 nanoseconds without hysteresis.
